(19) United States
(12) Patent Application Publication
(10) Pub. No.: US 2014/0196762 A1
(43) Pub. Date: Jul. 17, 2014

(54) METHODS FOR FORMING OPTIMIZED LENSES AND DEVICES THEREOF

(71) Applicants: Arthur J. Davis, Schaghticoke, NY (US); Steve Scott, Avon, CT (US)

(72) Inventors: Arthur J. Davis, Schaghticoke, NY (US); Steve Scott, Avon, CT (US)

(73) Assignee: ORAFOL AMERICAS INC., Avon, CT (US)

(21) Appl. No.: 14/124,543

(22) PCT Filed: Jun. 15, 2012
(86) PCT No.: PCT/US12/42773

§ 371 Date: Feb. 21, 2014

Related U.S. Application Data
(60) Provisional application No. 61/498,288, filed on Jun. 17, 2011.

(51) Int. Cl. G02B 3/08; H01L 31/052; H01L 31/18

(52) U.S. Cl. CPC G02B 3/08; H01L 31/18; H01L 31/0524
USPC 136/246; 359/742; 82/1.11

(57) ABSTRACT

This technology relates generally to methods for the fabrication of high performance lenses, in particular, lenses including a glass carrier and an at least partially transmissive layer with one or more slope facets coupled together by one of more draft facets on a surface of the glass carrier. The methods involve identifying geometric errors in the slope and draft facets to create correction factors and forming corrected slope and draft facets based on the correction factors. This technology also relates to the resulting lenses and lens arrays.

This application claims the benefit of U.S. Provisional Patent Application Ser. No. 61/498,288, filed Jun. 17, 2011, which is hereby incorporated by reference in its entirety.

### FIELD OF THE INVENTION

This technology relates generally to methods for the fabrication of lenses, and more particularly to the fabrication of high performance silicone-on-glass Fresnel lenses. This technology also relates to the resulting lenses and lens arrays.

### BACKGROUND

Improving the efficiency of solar cells is critical for increased deployment which will result in the subsequent reduction of greenhouse gas emissions. This issue has become even more urgent as countries seek clean alternative energy sources. However, this must be accomplished at a competitive cost with respect to other energy sources.

One solution gaining momentum is the branch of solar power known as concentrator photovoltaics (CPV) and concentrated solar power (CSP), where the cost reduction is derived from replacing inefficient photovoltaic (PV) cell material with lower cost optical systems. A typical concentrating photovoltaic (CPV) apparatus includes a lens array positioned to focus solar energy onto a corresponding array of photovoltaic cells for the generation of electricity. Typically, the lens used to concentrate the solar light onto the photocell is a Fresnel lens comprising a superstrate or carrier and a Fresnel optical structure. The Fresnel optical structure includes a multitude of prism facets at prescribed angles.

Silicone-on-glass (SOG) primary optics are one option for use in CPVs and in CSP arrays. In an SOG optic, the Fresnel lens is a hybrid made out of glass as a carrier and a silicone layer (or other flexible highly transmissive and UV stable polymers) with the Fresnel structure cast onto the underside or side toward the photocell. Thus, in these SOG primary optics, the glass carrier is exposed to the weather side while a microstructured Fresnel lens made of silicone is on the inside surface of the primary optic, where it is protected from exposure to the elements. These SOG CPVs or CSPs are useful in solar panels/modules, as they require only a very thin silicone layer and are very durable, exhibiting resistance to water, extreme temperatures, and other environmental factors.

The glass in the SOG structure typically has a coefficient of thermal expansion of 8-10 ppm/° C. which differs from the silicone which typically has a coefficient of thermal expansion in the range of 20-50 ppm/° C. As explained below, this difference can result in manufacturing problems.

The Fresnel lens is manufactured by thermally curing the silicone at an elevated temperature. At the cure temperature, the glass is larger in size than it is when at ambient temperature. When the Fresnel lens is brought back to ambient, the Fresnel structure in the silicone deviates from the shape of the mold due to the different rates of shrinkage of the glass and the silicone. The glass ends up with a low amount of tensile stress due to the strength of the material composition and the silicone has a higher value of compressive stress which introduces deviations from the optical design values resulting in some light curvature in the slopes. This change in dimension causes stress in facets of the Fresnel structure in the silicone which causes the facets to change shape and have a curved surface rather than the straight facet of the mold. This shape change causes the Fresnel lens performance to deviate from optimum leading to losses in optical efficiency.

As such, there is a need for a method of making a lens that compensates for the deviations from the optical design incurred as a result of the typical manufacturing and curing processes. There is also a need to provide a lens that does not suffer from the performance degradation of the prior art. This technology is directed to overcoming these and other deficiencies in the prior art.

### SUMMARY OF THE INVENTION

This technology relates to a method for making a lens. This method involves providing a first glass carrier, providing a first at least partially transmissive layer on a surface of the first glass carrier, forming one or more slope facets coupled together by one or more draft facets on a surface of the first at least partially transmissive layer, identifying geometric errors in the one or more slope facets and one or more draft facets of the first at least partially transmissive layer to create correction factors, and forming corrected one or more slope facets coupled together by one or more draft facets on a surface of a second at least partially transmissive layer on a surface of a second glass carrier based on the correction factors.

This technology further relates to a lens made by the above method. The lens comprises a glass carrier and an at least partially transmissive layer on a surface of the glass carrier, wherein the at least partially transmissive layer has one or more slope facets coupled together by one or more draft facets on a surface thereof. The one or more slope facets coupled together by one or more draft facets are corrected slope and draft facets formed based on correction factors determined by geometric errors identified in facets of a lens structure.

This technology further relates to a system including an array of lenses described herein and an array of photovoltaic cells configured with respect to the array of lenses to convert light energy passing through the array of lenses into electricity.

In a typical silicone-on-glass optic product, the slope and draft facet intersections of the optic structure are cast as valleys in the silicone nearly contacting the glass. The product is treated at elevated temperatures to cure the silicone; however, the final product at room temperature has a different dimensional shape from the theoretical shape or shape of the tool used to form the lens due to stress deformation. In addition, geometric errors resulting from inaccuracies in the tool used to manufacture the lens and tooling replication errors give rise to deviations from the optical design and performance degradation. The methods and devices described herein overcome these geometric errors in the facets of the lens.

### BRIEF DESCRIPTION OF THE DRAWINGS

FIG. 1 is a functional block diagram illustrating a method for making a lens in accordance with one embodiment of the present invention;

FIG. 2 is a cross-sectional view of a lens in accordance with one embodiment of the present technology;

FIG. 3 shows deformation of the slope of a prism facet of a Fresnel lens according to a spline profile in accordance with one embodiment of the present invention; and

FIG. 4 is a graph showing the index of refraction at different temperatures for an exemplary silicone material in accordance with one embodiment of the present invention.

### DETAILED DESCRIPTION OF THE INVENTION

This technology relates to methods for making a lens and devices thereof.

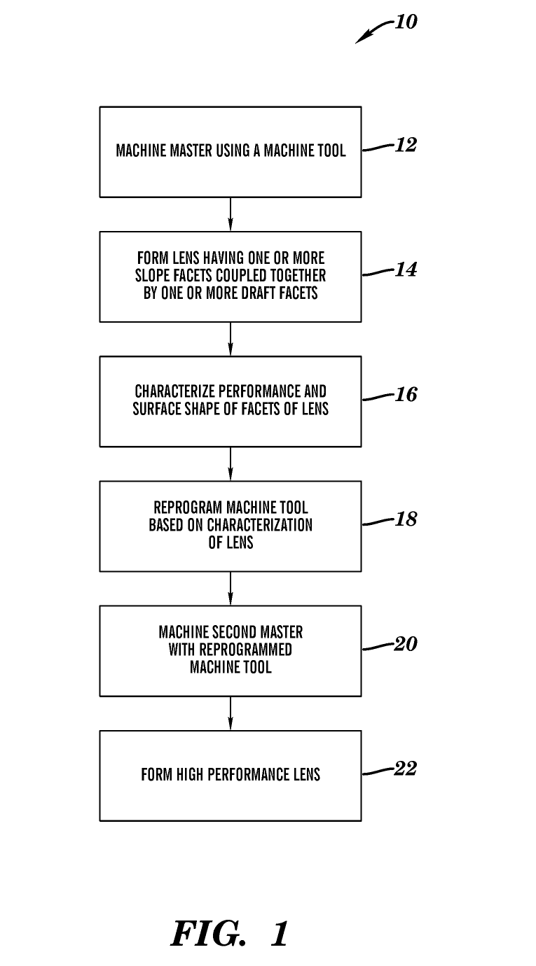

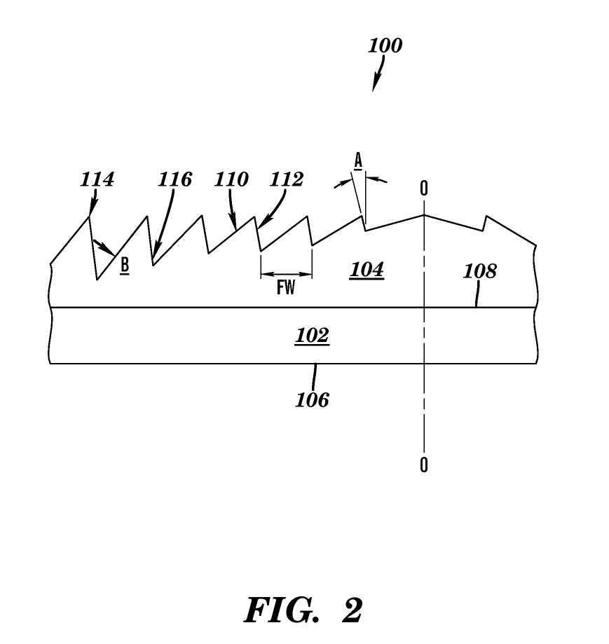

Referring to FIG. 1, a method 10 for fabricating a lens in accordance with one embodiment of this technology is illustrated. The lens may be a Fresnel lens comprising multitudes of prism facets, including one or more slope facets coupled together by one or more draft facets as shown, for example, in FIG. 2. With this technology, high performance, optimized lenses are produced which compensate for errors produced by tool inaccuracies, tooling replication errors, and the thermal coefficient of expansion mismatch between the glass carrier and the at least partially transmissive layer which causes changes in dimension due to the different rates of thermal expansion of the glass and the at least partially transmissive layer.

At step 12, a master for forming an optical structure in a lens is formed using a machine tool. In one embodiment, the master is machined with a machine tool for forming slope and draft facets in a lens. The master may be formed using a single point diamond cutting tool, although a master formed using other cutting tools may be used. The master may include slope and draft facets prescribed to perform the desired concentrating function. Suitable materials for the master include, but are not limited to, brass, aluminum, high phosphorous nickel, and polymers.

In step 12, the theoretical dimensions and shape of the slope facets and draft facets of the lens are calculated based on the desired properties of the lens. The machine tool is then programmed using these calculations and the master is machined. Software to achieve the optical design of the slope and draft facets can be custom designed. Once machined, the master can be replicated so that it can be used to form the desired optical structure. Techniques for replicating the master include electroforming which is described, for example, in U.S. Pat. No. 4,501,646, which is hereby incorporated by reference in its entirety.

In one aspect of this technology, the master may be formed using a high precision machine tool, such as a single point diamond tool, resulting in a master having less than two microns of peak and valley rounding or wear due to the cutting forces. This allows the formation of sharp peaks and valleys which results in a higher performing lens. The machine tool may have a high structural stiffness, high positional accuracy and repeatability of the rotational and translation axes, and ample vibration isolation.

Examples of machine tools with the required stiffness include the Nanoform 250 single point diamond turning lathe made by Ametek. The hydrostatic slides and air bearing work holding spindle are designed to make optical structures in metal such as Fresnel lens masters. These machine tools use high resolution optical encoders (0.016 micrometer feedback resolution) to provide feedback enabling movements of the axes to sub-micron levels. These machines are built with hydrostatic slides that have straightness of travel in the 10 micrometer range over their full travel and stiffness. The rotational accuracy is in the 2 arc-second range which is also required for machining Fresnel lens masters. The rotary axes have stiffness of 225 and 600 Newton/micron for the radial and axial stiffness, respectively. Vibration isolation is achieved through a combination of mass dampening using a granite base and active isolators supporting the machine tool.

In one embodiment, the master is formed to produce slope facets with a smooth or low root mean square (RMS) surface finish to avoid scattering of light from the reflective surfaces. In one embodiment, a surface finish for the slope facets of less than five Angstrom RMS is provided. In another embodiment, a surface finish for the slope facets of less than three Angstrom RMS is provided.

In another embodiment, the cutting technique for machining the master involves setting the diamond tool face parallel to the master substrate and then rotating this surface to the prescribed angle on each successive facet. As described above, the optical design for the slope and draft facets may be programmed into machine code. The optical prescription for the surface of a straight slope Fresnel lens is a definition of the angle of each facet at a given location on the surface of the lens. The ability to machine this prescription into the master requires that the design be translated into machine code so that each groove is positioned correctly and the diamond tool is rotated to the proper angle.

Referring again to FIG. 1, at step 14 the replicated master is used to form a lens having one or more slope facets coupled together by one or more draft facets. In one embodiment, the lens includes a glass carrier and an at least partially transmissive layer on a surface of the glass carrier. The replicated master is used to form the one or more slope facets coupled together by one or more draft facets in the at least partially transmissive layer.

The glass carrier provides a superstrate or carrier for the partially transmissive layer, although other materials may be applied to the glass carrier.

In one exemplary embodiment, the glass carrier has a thickness of from about 2.0 mm to about 6.0 mm. In another embodiment, the refractive index of the glass carrier is between about 1.515 and about 1.519. In a further embodiment, the glass carrier is a low iron float glass with less than about 0.4% iron content. In yet another embodiment, the glass carrier is partially heat strengthened per TVG DIN EN 1863, A2.

At step 14, a material is selected to be cast on the glass carrier to provide the at least partially transmissive layer of the lens. As used herein, the term “at least partially transmissive” means a material which at least partially allows the transmission of light therethrough. In one embodiment, the at least partially transmissive layer is highly transmissive allowing substantially all light from a particular light source to pass therethrough. The light source can be any suitable light source including, but not limited to, sunlight, lamplight, and artificial light.

In one exemplary embodiment, the material selected for the at least partially transmissive layer is silicone, although other materials, such as flexible, highly transmissive, and UV stable polymers, may be used. Suitable at least partially transmissive layers include, but are not limited to, Dow Corning Sylgard 184 or equivalents and single component optically clear silicones.

In one embodiment, the material selected for the at least partially transmissive layer has a cure temperature which is substantially the same as a selected operating temperature range of the lens. In one particular embodiment, the cure temperature is at or below the selected operating temperature range of the lens. In one embodiment, the material selected is a customized silicone which cures faster at a lower temperature. Such customized silicones can be created based on the desired cure temperature and rate and are available, for example, as Loctite 5033 Nuva-Sil Silicone.

In one embodiment, the at least partially transmissive layer having one or more slope facets coupled together by one or more draft facets forms a Fresnel lens. In one embodiment, the facet angles of the Fresnel lens are designed such that a minimal spot diameter is achieved at a nominal focal length for one wavelength of light. Shorter and longer wavelengths will have a larger diameter at this nominal focal distance (having minimal spot diameters located above and below this nominal distance). Secondary optical elements (SOE) may be utilized to improve the concentration of the shorter and longer wavelengths of light. In another embodiment, the Fresnel lens includes a multi-focus approach. Multiple groove bands are used to focus a set of specific wavelengths. A set of adjacent facets may be associated with a specific set of wavelengths, with each prism shape crafted to focus an associated wavelength. This design method can direct light nominally to the photovoltaic cell location or to the SOE acceptance area in a CPV.

Techniques for forming a lens including one or more slope facets coupled together by one or more draft facets are known in the art and are described, for example, in U.S. Pat. No. 4,170,616, which is hereby incorporated by reference in its entirety.

In step 16, the performance and surface shape of the facets of one or more lenses made with the replicated master are characterized to identify correction factors. Such correction factors can be based on any errors in the dimensions of the slope and draft facets of the lens(es) produced and are adjustments to the geometry of the optical design based on the errors that are found.

The correction factors may be based on the accuracy and repeatability of the machine tool. For example, the correction factors may be generated based on measurements of the machine axes' straightness of travel or rotational accuracy, and positioning repeatability of the axes. These correction factors may be used to compensate for these errors from the true position or rotation of the axis to make the part better match the design prescription.

In a further embodiment, the correction factors may include tooling replication induced dimensional changes. The master is replicated by electroforming and this process can introduce dimensional changes making the position and angle of the facets change from nominal. Quantifying the changes and using this data to compensate the program for the lens machining will make the final product more like the optical prescription.

The correction factors may also include polymer processing induced dimensional changes. The master tool is replicated by electroforming and then the final optic is made by compression molding, injection molding, or casting a polymer. All of these polymer processes have specific material shrinkage after formation of the structure that can be quantified. Compensation of this shrinkage into the programming of the lens structure will make the final part more like the desired optical prescription and increase the performance of the part.

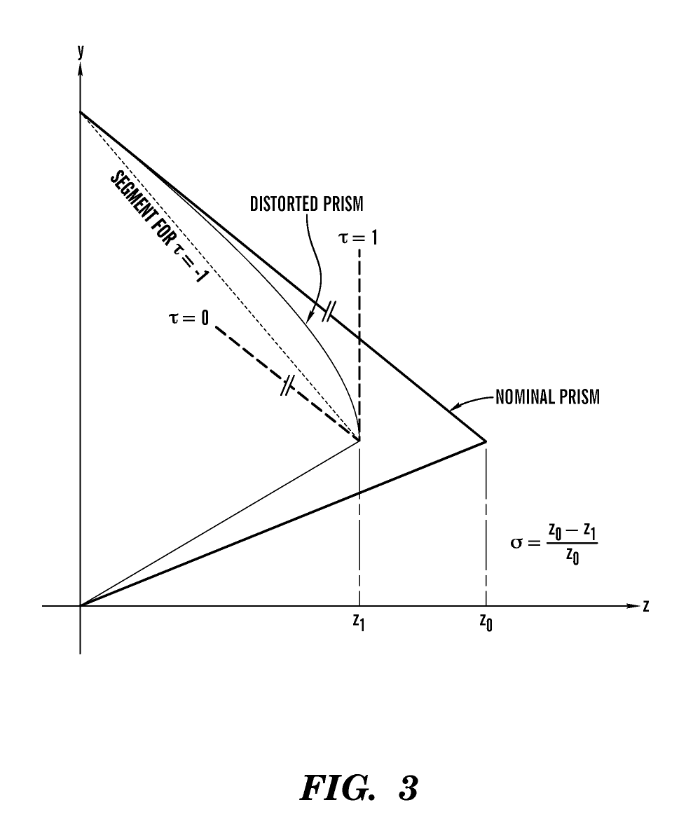

In one embodiment, an exemplary method has been developed which characterizes the deformed the slope of the prism facet according to a spline profile and is illustrated in FIG. 3. In particular, the correction is defined as a spline profile and subtracted from the theoretical slope profile. The resultant is then used as the corrected shape of the slope surface.

Once the errors and correction factors have been determined in step 16, the machine tool is reprogrammed in step 18 to compensate for the errors found during characterization. Software to accomplish the optical design may be custom designed to incorporate correction factors for the accuracy and repeatability of the machine tool and to compensate for further processing.

In step 20, a second master is machined with the reprogrammed machine tool based on the compensated optic design. The master can then again be replicated, as described above and, in step 22, a high performance lens is produced which compensates for the various geometric errors typically produced during processing.

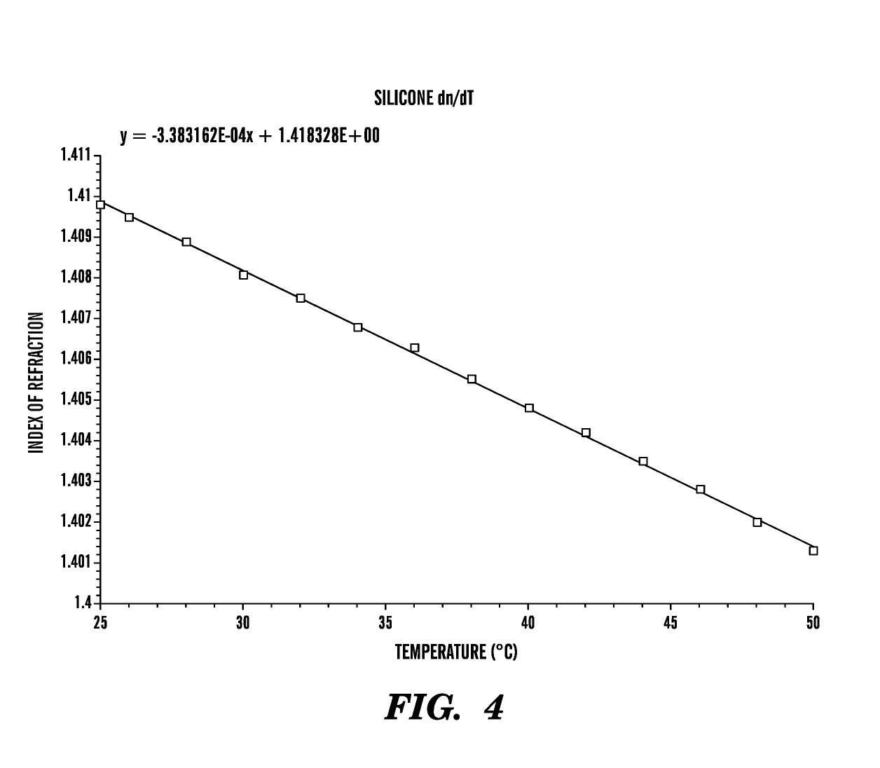

As illustrated in FIG. 4, the index of refraction of silicone has temperature dependence. The temperature dependence may also be used to design a master for a lens to perform optimally for different normal operating temperatures. For example, if the operational temperature range for a CPV apparatus is known, then the prism prescription can be composed for optimal performance using the refractive index values for the silicone in this range. Different curing temperatures or different silicone materials could be used for various geographic locations depending on the average operating temperature at that location.

Referring to FIG. 2, a lens 100 made in accordance with one embodiment of this technology is illustrated. The lens 100 includes a glass carrier 102 and an at least partially transmissive layer 104. The glass carrier 102 has a first surface 106 and a second surface 108. In one embodiment, the first surface 106 of the glass carrier 102 is exposed to the weather when used in a CPV.

Suitable dimensions and properties for the glass carrier 102 are described above.

Referring to FIG. 2, the at least partially transmissive layer 104 is adjacent the second surface 108. As used herein, the term “adjacent” means that the glass carrier and at least partially transmissive layer may or may not be in contact, but there is the absence of anything of the same kind in between. In the embodiment shown in FIG. 2, the at least partially transmissive layer 104 is adjacent and in contact with the second surface 108.

In one exemplary embodiment, the at least partially transmissive layer is a silicone layer. Suitable at least partially transmissive layers are described above. In one exemplary embodiment, the at least partially transmissive layer 104 has a thickness of from about 0.1 mm to about 2.0 mm. In another embodiment, the refractive index of the at least partially transmissive layer 104 is between about 1.405 and about 1.420 when measured at the sodium D-line with 589 nanometer wavelength and 21° C.

The at least partially transmissive layer 104 includes one or more slope facets 110 coupled together by one or more draft (or relief) facets 112. The slope and draft facets 110, 112 form facet peaks 114 and facet valleys 116. Referring to FIG. 2, the facet angle B and draft angle A, as well as the facet width or pitch FW and optical axis O are shown. The particular dimensions of the slope and draft facets 110, 112 and the resulting facet angle, draft angle, and pitch are determined based on the intended use and properties of the lens array. The angles of the facets typically are from zero or parallel to the surface up to a maximum of approximately 42 degrees from the surface. The height of the facets can be constant or variable and range typically from about 0.1 mm to about 1.0 mm based on the optical design. Typical pitch or facet spacing can be constant or variable and range from about 0.2 mm to about 0.9 mm.

In the embodiment shown in FIG. 2, the at least partially transmissive layer with one or more slope facets coupled together by one or more draft facets forms a Fresnel lens.

In another embodiment, the slope and draft facets are corrected slope and draft facets formed with correction factors determined by geometric errors identified by characterization of the facets of a lens structure using the methods described above.

A further aspect of this technology relates to a system including an array of lenses of any of the embodiments described above and an array of photovoltaic cells configured with respect to the array of lenses to convert light energy passing through the array of lenses into electricity.

In one embodiment, the system is a CPV apparatus. To further optimize the design of the lens given the full-solar spectrum and the uniformity needed at the photovoltaic cell, secondary optical elements (SOEs) and reflectors also can be incorporated into the CPV apparatus.

As discussed above, various techniques can be employed to focus the solar wavelengths onto a photovoltaic cell with a Fresnel lens. This exemplary technology enables those various techniques to be optimized to yield maximum efficiency of the photovoltaic cell. If a spot-focus Fresnel lens is used, light from the design wavelength will have a minimum beam diameter on the photovoltaic cell. The location of the photovoltaic cell could be adjusted higher or lower to defocus the spot and achieve a more uniform irradiance and thus increase the cell efficiency. Naturally, the lower and higher wavelengths will not focus to the same diameter and must be balanced as a trade-off based on the characteristics of the photovoltaic cell or alternatively can be recovered using an additional collection optic or SOE. Typical embodiments of SOE's include glass TIR reflectors or metallic based reflectors placed directly above the photovoltaic cell.

CPV apparatuses may or may not utilize a SOE. Some advantages of an SOE include increased tolerance to tracking error, improved irradiance uniformity on the photovoltaic cell, improved efficiency over a broad spectral range, increased concentration ratio, and improved allowance for assembly tolerances. On the other hand, the addition of a SOE increases the cost of the apparatus, adds to the assembly complexity and increases the number of possible failure modes.

Having thus described the basic concept of the invention, it will be rather apparent to those skilled in the art that the foregoing detailed disclosure is intended to be presented by way of example only, and is not limiting. Various alterations, improvements, and modifications will occur and are intended to those skilled in the art, though not expressly stated herein. These alterations, improvements, and modifications are intended to be suggested hereby, and are within the spirit and scope of the invention. Additionally, the recited order of processing elements or sequences, or the use of numbers, letters, or other designations therefore, is not intended to limit the claimed processes to any order except as may be specified in the claims. Accordingly, the invention is limited only by the following claims and equivalents thereto.

What is claimed is:

1. A method for making a lens, the method comprising:
providing a first glass carrier;
providing a first at least partially transmissive layer on a surface of the first glass carrier;
forming one or more slope facets coupled together by one or more draft facets on a surface of the first at least partially transmissive layer;
identifying geometric errors in the one or more slope facets and one or more draft facets of the first at least partially transmissive layer to create correction factors; and
forming corrected one or more slope facets coupled together by one or more draft facets on a surface of a second at least partially transmissive layer on a surface of a second glass carrier using the correction factors.

2. The method as set forth in claim 1 wherein the first and second at least partially transmissive layer is silicone.

3. The method as set forth in claim 1 wherein the first and second at least partially transmissive layer has a cure temperature which is substantially the same as a selected operating temperature range of the lens.

4. The method as set forth in claim 1 wherein the forming one or more slope facets coupled together by one or more draft facets further comprises:
obtaining a first master machined with a machine tool to form the one or more slope facets coupled together by one or more draft facets in the at least partially transmissive layer; and
forming with the first master the one or more slope facets coupled together by one or more draft facets in the at least partially transmissive layer.

5. The method as set forth in claim 4 wherein the first master has less than two microns of peak and valley rounding.

6. The method as set forth in claim 4 wherein the obtaining the first master comprises machining the first master with a machine tool with structural stiffness, positional accuracy, repeatability of rotational and translation axes, and vibration isolation.

7. The method as set forth in claim 1 wherein the forming corrected one or more slope facets coupled together by one or more draft facets further comprises:
obtaining a second master with a machine tool to form the corrected one or more slope facets coupled together by one or more draft facets in the second at least partially transmissive layer; and
forming with the second master the corrected one or more slope facets coupled together by one or more draft facets in the second at least partially transmissive layer.

8. The method as set forth in claim 7 wherein the second master has less than two microns of peak and valley rounding.

9. The method as set forth in claim 7 wherein the obtaining the second master comprises machining the second master with a machine tool with structural stiffness, positional accuracy, repeatability of rotational and translation axes, and vibration isolation.

10. The method as set forth in claim 1 wherein the correction factors are based on inaccuracies in a machine tool used to manufacture a first master for forming the one or more slope facets coupled together by one or more draft facets.

11. The method as set forth in claim 1 wherein the correction factors are based on replication induced dimensional changes.

12. The method as set forth in claim 1 wherein the correction factors are based on material processing induced dimensional changes of the first at least partially transmissive layer.

13. The method as set forth in claim 1 wherein the corrected one or more slope facets coupled together by one or more draft facets form a Fresnel optical structure.

14. The method as set forth in claim 1 further comprising providing a surface finish for the corrected one or more slope facets below five Angstrom RMS.

15. The method as set forth in claim 1 further comprising providing a surface finish for the corrected one or more slope facets below three Angstrom RMS.

16. A lens comprising:
a glass carrier; and
an at least partially transmissive layer on a surface of the glass carrier, wherein the at least partially transmissive layer has one or more slope facets coupled together by one or more draft facets on a surface thereof, wherein the one or more slope facets coupled together by one or more draft facets are corrected slope and draft facets formed with correction factors determined by geometric errors identified in facets of a lens structure.

17. The lens as set forth in claim 16 wherein the at least partially transmissive layer is silicone.

18. The lens as set forth in claim 16 wherein the at least partially transmissive layer has a cure temperature which is substantially the same as a selected operating temperature range of the lens.

19. The lens as forth in claim 16 wherein the at least partially transmissive layer with one or more slope facets coupled together by one or more draft facets forms a Fresnel optical structure.

20. The lens as set forth in claim 16 wherein the correction factors are based on inaccuracies in a machine tool used to manufacture a master for forming the one or more slope facets coupled together by one or more draft facets.

21. The lens as set forth in claim 16 wherein the correction factors are based on replication induced dimensional changes.

22. The lens as set forth in claim 16 wherein the correction factors are based on material processing induced dimensional changes of the at least partially transmissive layer.

23. The lens as set forth in claim 16 wherein a surface finish of the corrected one or more slope facets is below five Angstrom RMS.

24. The lens as set forth in claim 16 wherein a surface finish of the corrected one or more slope facets is below three Angstrom RMS.

25. A system comprising:
an array of lenses according to claim 16; and
an array of photovoltaic cells configured with respect to the array of lenses to convert light energy passing through the array of lenses into electricity.
